(19) United States
(12) Patent Application Publication
(10) Pub. No.: US 2017/0018222 A1
(43) Pub. Date: Jan. 19, 2017

(54) ORGANIC LIGHT EMITTING DISPLAY DEVICE

(71) Applicant: Samsung Display Co., Ltd., Yongin-si (KR)

(72) Inventors: Gyung-Soon PARK, Seoul (KR); Kyung-Hoon KIM, Uiwang-si (KR); Il-Gon KIM, Seoul (KR); Min-Jae JEONG, Suwon-si (KR); Kang-Moon JO, Hwaseong-si (KR); Seon-Young CHOI, Gunpo-si (KR)

(21) Appl. No.: 15/004,606

(22) Filed: Jan. 22, 2016

(30) Foreign Application Priority Data
Jul. 15, 2015 (KR) 10-2015-0100300

(51) Int. Cl. G09G 3/3208; H01L 27/32

(52) U.S. Cl. CPC G09G 3/3208; H01L 27/3244; G09G 2320/02

(57) ABSTRACT

An organic light emitting display device includes first to third pixels arranged in a first direction, first to third gate lines respectively connected to the first to third pixels, first to third initialization control lines respectively connected to the first to third pixels, first to third light emission control lines respectively connected to the first to third pixels, a driving control signal supplying line connected to at least one of the first to third gate lines and at least one of the first to third initialization control lines, a light emission control signal supplying line connected to at least two of the first to third light emission control lines, a gate driver connected to the driving control signal supplying line, and a light emission control driver connected to the light emission control signal supplying line.

### CROSS-REFERENCE TO RELATED APPLICATION

This application claims priority to and the benefit of Korean Patent Application No. 10-2015-0100300, filed on Jul. 15, 2015 in the Korean Intellectual Property Office (KIPO), the entire disclosure of which is incorporated herein by reference.

### BACKGROUND

1. Field

Example embodiments relate to display devices. More particularly, example embodiments relate to organic light emitting display devices.

2. Description of the Related Art

An organic light emitting display device may include a plurality of pixels, a data driver for transferring data signals to data lines, a gate driver for transferring gate signals to gate lines, a light emission control driver for transferring light emission control signals to light emission control lines, etc. In general, the data driver may be located at an upper-side or a lower-side of a display panel, and the gate driver and the light emission control driver may be located at a left-side and/or a right-side of the display panel. Here, the data driver may be connected to the plurality of pixels through the data lines that extend in a column direction, the gate driver may be connected to the plurality of pixels through the gate lines that extend in a row direction, and the light emission control driver may be connected to the plurality of pixels through the light emission control lines that extend in the row direction.

An area on which the gate driver and the light emission control driver are disposed may be a non-display area, and thus a dead space on the left-side and/or the right-side of the display panel may be present. Recently, technologies that dispose the gate driver and the light emission control driver on a side on which the data driver is disposed have been developed to reduce the dead space of the display panel.

As the gate driver and the light emission control driver are located at the upper-side and/or the lower-side of the display panel as mentioned above, the dead space on the left-side and the right-side of the display panel may decrease, however the dead space on the upper-side and/or the lower-side of the display panel may increase. Moreover, because lines extending in the column direction to connect the gate driver and the light emission control driver to the gate lines and the light emission control lines, respectively, are added, an area that the lines extending in the column direction occupy on a display area of the display panel may increase.

### SUMMARY

Example embodiments provide an organic light emitting display device in which the number of lines extending in a column direction is reduced by connecting at least two of light emission control lines to a light emission control signal supplying line and by connecting a gate line and an initialization control line to a driving control signal supplying line.

Example embodiments provide the organic light emitting display device in which the number of the lines extending in the column direction is reduced by connecting at least two of the light emission control lines to the light emission control signal supplying line and by connecting the gate line and a bypass control line to the driving control signal supplying line.

Example embodiments provide the organic light emitting display device in which the number of the lines extending in the column direction is reduced by connecting at least two of the light emission control lines to the light emission control signal supplying line and by connecting the initialization control line and the bypass control line to the driving control signal supplying line.

According to example embodiments, an organic light emitting display device may include a first pixel, a second pixel, and a third pixel arranged in a first direction on a display area of a display panel, a data line connected to the first pixel, the second pixel, and the third pixel and extending in the first direction on the display area, a first gate line, a second gate line, and a third gate line respectively connected to the first pixel, the second pixel, and the third pixel and extending in a second direction perpendicular to the first direction on the display area, a first initialization control line, a second initialization control line, and a third initialization control line respectively connected to the first pixel, the second pixel, and the third pixel and extending in the second direction on the display area, a first light emission control line, a second light emission control line, and a third light emission control line respectively connected to the first pixel, the second pixel, and the third pixel and extending in the second direction on the display area, a driving control signal supplying line connected to at least one of the first gate line, the second gate line, and the third gate line and at least one of the first initialization control line, the second initialization control line, and the third initialization control line, and extending in the first direction on the display area, a light emission control signal supplying line connected to at least two of the first light emission control line, the second light emission control line, and the third light emission control line and extending in the first direction on the display area, a data driver connected to the data line to supply a data signal and located at a drivers placement area, a gate driver connected to the driving control signal supplying line to supply a driving control signal and located at the drivers placement area, and a light emission control driver connected to the light emission control signal supplying line to supply a light emission control signal and located at the drivers placement area. The drivers placement area is located outside the display area in the first direction and included in a non-display area.

In some example embodiments, the light emission control signal supplying line may be connected to the first light emission control line and the second light emission control line.

In some example embodiments, the light emission control signal supplying line may be connected to the first light emission control line, the second light emission control line, and the third light emission control line.

In some example embodiments, the driving control signal supplying line may be connected to the first gate line and the second initialization control line.

In some example embodiments, the organic light emitting display device may further include a first bypass control line, a second bypass control line, and a third bypass control line respectively connected to the first pixel, the second pixel, and the third pixel and extending in the second direction on the display area.

In some example embodiments, the light emission control signal supplying line may be connected to the first light emission control line and the second light emission control line.

In some example embodiments, the light emission control signal supplying line may be connected to the first light emission control line, the second light emission control line, and the third light emission control line.

In some example embodiments, the driving control signal supplying line may be connected to the first gate line and the second initialization control line.

According to example embodiments, an organic light emitting display device may include a first pixel, a second pixel, and a third pixel arranged in a first direction on a display area of a display panel, a data line connected to the first pixel, the second pixel, and the third pixel and extending in the first direction on the display area, a first gate line, a second gate line, and a third gate line respectively connected to the first pixel, the second pixel, and the third pixel and extending in a second direction perpendicular to the first direction on the display area, a first initialization control line, a second initialization control line, and a third initialization control line respectively connected to the first pixel, the second pixel, and the third pixel and extending in the second direction on the display area, a first bypass control line, a second bypass control line, and a third bypass control line respectively connected to the first pixel, the second pixel, and the third pixel and extending in the second direction on the display area, a first light emission control line, a second light emission control line, and a third light emission control line respectively connected to the first pixel, the second pixel, and the third pixel and extending in the second direction on the display area, a driving control signal supplying line connected to at least one of the first gate line, the second gate line, and the third gate line and at least one of the first bypass control line, the second bypass control line, and the third bypass control line, and extending in the first direction on the display area, a light emission control signal supplying line connected to at least two of the first light emission control line, the second light emission control line, and the third light emission control line and extending in the first direction on the display area, a data driver connected to the data line to supply a data signal and located at a drivers placement area, a gate driver connected to the driving control signal supplying line to supply a driving control signal and located at the drivers placement area, and a light emission control driver connected to the light emission control signal supplying line to supply a light emission control signal and located at the drivers placement area. The drivers placement area is located outside the display area in the first direction and included in a non-display area.

In some example embodiments, the light emission control signal supplying line may be connected to the first light emission control line and the second light emission control line.

In some example embodiments, the light emission control signal supplying line may be connected to the first light emission control line, the second light emission control line, and the third light emission control line.

In some example embodiments, the driving control signal supplying line may be connected to the first gate line and the first bypass control line.

In some example embodiments, the driving control signal supplying line may be further connected to at least one of the first initialization control line, the second initialization control line, and the third initialization control line.

In some example embodiments, the driving control signal supplying line may be connected to the first gate line, the second initialization control line, and the first bypass control line.

In some example embodiments, the driving control signal supplying line may be connected to the first gate line, the second initialization control line, and the second bypass control line.

According to example embodiments, an organic light emitting display device may include a first pixel, a second, pixel, and a third pixel arranged in a first direction on a display area of a display panel, a data line connected to the first pixel, the second pixel, and the third pixel and extending in the first direction on the display area, a first gate line, a second gate line, and a third gate line respectively connected to the first pixel, the second pixel, and third pixel and extending in a second direction perpendicular to the first direction on the display area, a first initialization control line, a second initialization control line, and a third initialization control line respectively connected to the first pixel, the second pixel, and the third pixel and extending in the second direction on the display area, a first bypass control line, a second bypass control line, and a third bypass control line respectively connected to the first pixel, the second pixel, and the third pixel and extending in the second direction on the display area, a first light emission control line, a second light emission control line, and a third light emission control line respectively connected to the first pixel, the second pixel, and the third pixel and extending in the second direction on the display area, a driving control signal supplying line connected to at least one of the first initialization control line, the second initialization control line, and the third initialization control line and at least one of the first bypass control line, the second bypass control line, and the third bypass control line, and extending in the first direction on the display area, a light emission control signal supplying line connected to at least two of the first light emission control line, the second light emission control line, and the third light emission control line and extending in the first direction on the display area, a data driver connected to the data line to supply a data signal and located at a drivers placement area, a gate driver connected to the driving control signal supplying line to supply a driving control signal and located at the drivers placement area, and a light emission control driver connected to the light emission control signal supplying line to supply a light emission control signal and located at the drivers placement area. The drivers placement area is located outside the display area in the first direction and included in a non-display area.

In some example embodiments, the light emission control signal supplying line may be connected to the first light emission control line and the second light emission control line.

In some example embodiments, the light emission control signal supplying line may be connected to the first light emission control line, the second light emission control line, and the third light emission control line.

In some example embodiments, the driving control signal supplying line may be connected to the first initialization control line and the first bypass control line.

Therefore, an organic light emitting display device according to example embodiments may reduce dead space, on a left-side or a right-side of a display panel and in an area occupied by lines extending in a column direction, by including a structure in which a data driver, a gate driver, and a light emission control driver are located at an upper-side or a lower-side of the display panel, and a light emission control signal supplying line is connected to at least two light emission control lines.

In addition, an organic light emitting display device according to example embodiments may further reduce an area occupied by lines extending in a column direction by including a structure in which a gate line of a first pixel and an initialization control line of a second pixel are connected to a driving control signal supplying line or a structure in which a gate line and a bypass control line of the first pixel are connected to the driving control signal supplying line.

### BRIEF DESCRIPTION OF THE DRAWINGS

Illustrative, non-limiting example embodiments will be more clearly understood from the following detailed description taken in conjunction with the accompanying drawings.

FIG. 1 is a diagram illustrating an organic light emitting display device in accordance with example embodiments.

FIG. 2 is a diagram illustrating an area X of the organic light emitting display device of FIG. 1.

FIGS. 3A and 3B are diagrams illustrating examples in which light emission control lines are connected to light emission control signal supplying lines in the organic light emitting display device of FIG. 1.

FIG. 4 is a diagram illustrating an example in which gate lines and initialization control lines are connected to driving control signal supplying lines in the organic light emitting display device of FIG. 1.

FIG. 5 is a diagram illustrating an example in which gate lines and bypass control lines are connected to driving control signal supplying lines in the organic light emitting display device of FIG. 1.

FIG. 6 is a diagram illustrating an example in which initialization control lines and bypass control lines are connected to driving control signal supplying lines in the organic light emitting display device of FIG. 1.

FIGS. 7A and 7B are diagrams illustrating examples in which gate lines, initialization control lines, and bypass control lines are connected to driving control signal supplying lines in the organic light emitting display device of FIG. 1.

FIG. 8 is a circuit diagram illustrating an example of a pixel included in the organic light emitting display device of FIG. 1.

FIG. 9 is a timing diagram for illustrating a method of driving the pixel of FIG. 8.

FIG. 10 is a circuit diagram illustrating another example of a pixel included in the organic light emitting display device of FIG. 1.

FIG. 11 is a timing diagram for illustrating a method of driving the pixel of FIG. 10.

### DETAILED DESCRIPTION

Hereinafter, example embodiments will be explained in detail with reference to the accompanying drawings.

It will be understood that, although the terms “first”, “second”, “third”, etc., may be used herein to describe various elements, components, regions, layers, and/or sections, these elements, components, regions, layers and/or sections should not be limited by these terms. These terms are used to distinguish one element, component, region, layer or section from another element, component, region, layer or section. Thus, a first element, component, region, layer, or section discussed below could be termed a second element, component, region, layer, or section, without departing from the spirit and scope of the present invention.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

The terminology used herein is for the purpose of describing particular embodiments and is not intended to be limiting of the present invention. As used herein, the singular forms “a” and “an” are intended to include the plural forms as well, unless the context clearly indicates otherwise. It will be further understood that the terms “comprise,” “comprises,” “comprising,” “includes,” “including,” and “include,” when used in this specification, specify the presence of stated features, integers, steps, operations, elements, and/or components, but do not preclude the presence or addition of one or more other features, integers, steps, operations, elements, components, and/or groups thereof.

As used herein, the term “and/or” includes any and all combinations of one or more of the associated listed items. Expressions such as “at least one of,” when preceding a list of elements, modify the entire list of elements and do not modify the individual elements of the list. Further, the use of “may” when describing embodiments of the present invention refers to “one or more embodiments of the present invention.” Also, the term “exemplary” is intended to refer to an example or illustration.

It will be understood that when an element or layer is referred to as being “on,” “connected to,” “coupled to,” “connected with,” “coupled with,” or “adjacent to” another element or layer, it can be “directly on,” “directly connected to,” “directly coupled to,” “directly connected with,” “directly coupled with,” or “directly adjacent to” the other element or layer, or one or more intervening elements or layers may be present. Further “connection,” “connected,” etc. may also refer to “electrical connection,” “electrically connect,” etc. depending on the context in which they are used as those skilled in the art would appreciate. When an element or layer is referred to as being “directly on,” “directly connected to,” “directly coupled to,” “directly connected with,” “directly coupled with,” or “immediately adjacent to” another element or layer, there are no intervening elements or layers present.

As used herein, the term “substantially,” “about,” and similar terms are used as terms of approximation and not as terms of degree, and are intended to account for the inherent deviations in measured or calculated values that would be recognized by those of ordinary skill in the art.

As used herein, the terms “use,” “using,” and “used” may be considered synonymous with the terms “utilize,” “utilizing,” and “utilized,” respectively.

Relevant devices or components according to embodiments of the present invention described herein may be implemented utilizing any suitable hardware, firmware (e.g. an application-specific integrated circuit), software, or a suitable combination of software, firmware, and hardware. For example, the various components of the device(s) may be formed on one integrated circuit (1C) chip or on separate IC chips. Further, the various components of the device(s) may be implemented on a flexible printed circuit film, a tape carrier package (TCP), a printed circuit board (PCB), or formed on a same substrate as one or more circuits and/or devices of another device. Further, the various components of the device(s) may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the exemplary embodiments of the present invention.

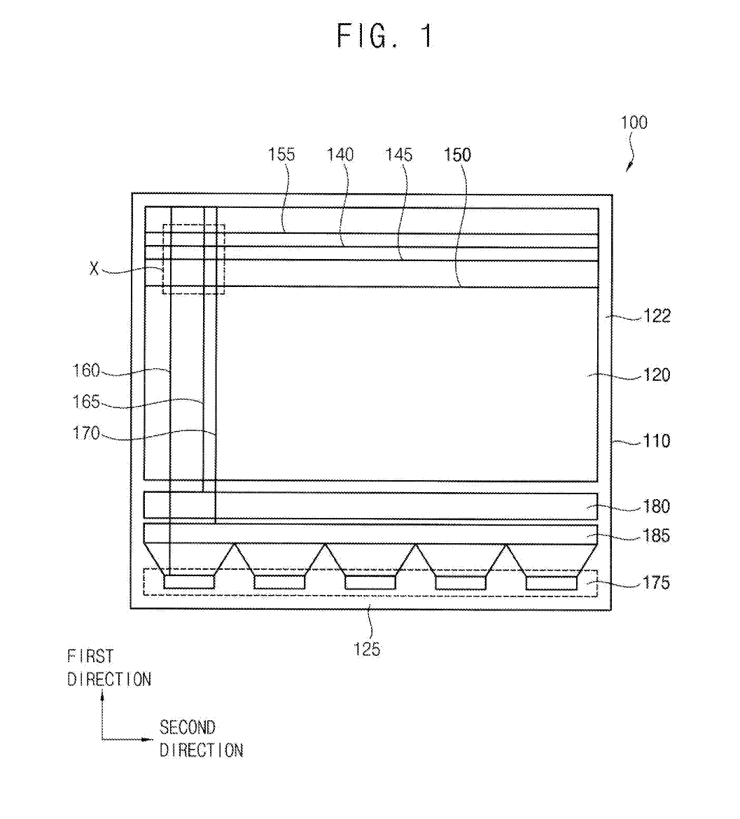

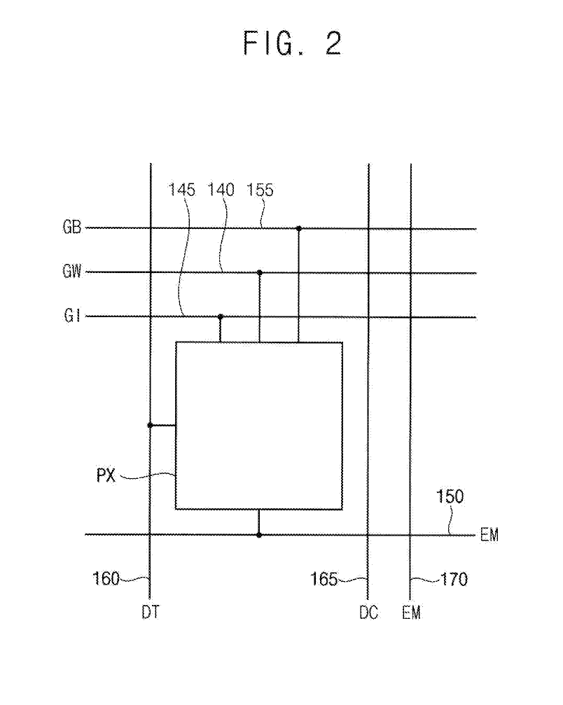

FIG. 1 is a diagram illustrating an organic light emitting display device in accordance with example embodiments. FIG. 2 is a diagram illustrating an area X of the organic light emitting display device of FIG. 1.

Referring to FIGS. 1 and 2, the organic light emitting display device 100 may include a display panel 110, a plurality of pixels PX, gate lines 140, initialization control lines 145, light emission control lines 150, data lines 160, driving control signal supplying lines 165, light emission control signal supplying lines 170, a data driver 175, a gate driver 180, and a light emission control driver 185. In some example embodiments, the organic light emitting display device 100 may further include bypass control lines 155.

The display panel 110 may include a display area 120 and a non-display area 122 formed around the display area 120.

The display area 120 may be an area on which images are displayed. In some example embodiments, the display area 120 may be located at a center region of the display panel 110.

The plurality of pixels PX may be arranged in a matrix structure on the display area 120. For example, the plurality of pixels PX may be arranged in the matrix structure that has N rows and M columns crossing each other, where N and M are positive integers.

The non-display area 122 may be a peripheral area on which drivers that drive the pixels PX located at the display area 120 and lines (e.g., signal lines) are disposed. In some example embodiments, the non-display area 122 may be located on the edge of the display panel 110. The non-display area 122 may substantially surround the display area 120.

A drivers placement area 125 may be an area on which the data driver 175, the gate driver 180, and the light emission control driver 185 are disposed. In some example embodiments, the drivers placement area 125 may be located outside the display area 120 in a first direction and included in the non-display area 122. For example, as illustrated in FIG. 1, the first direction may be an up-and-down (e.g., vertical) direction of the display panel 110.

The data driver 175 may generate a data signal DT and transfer the data signal DT to the pixels PX. In some example embodiments, a plurality of data driving circuits may compose the data driver 175. In other words, the data driver 175 may include the plurality of data driving circuits. An organic light emitting diode included in the pixels PX may emit light based on the data signal DT transferred from the data driver 175.

The gate driver 180 may generate a driving control signal DC including at least one of a gate signal GW, an initialization control signal GI, and a bypass control signal GB. The gate driver 180 may transfer the driving control signal DC to the pixels PX. In other words, the driving control signal DC may serve as at least one of the gate signal GW, the initialization control signal GI, and the bypass control signal GB. For example, a switching thin film transistor and a compensation thin film transistor included in the pixels PX may be switched based on the gate signal GW transferred from the gate driver 180, an initialization thin film transistor included in the pixels PX may be switched based on the initialization control signal GI transferred from the gate driver 180, and a bypass thin film transistor included in the pixels PX may be switched based on the bypass control signal GB transferred from the gate driver 180.

The light emission control driver 185 may generate a light emission control signal EM and transfer the light emission control signal EM to the pixels PX. For example, a first light emission control thin film transistor and a second light emission control thin film transistor included in the pixels PX may be switched based on the light emission control signal EM transferred from the light emission control driver 185.

In an example embodiment, the drivers placement area 125 may be one side of the non-display area 122. In other words, all of the data driver 175, the gate driver 180, and the light emission control driver 185 may be located at one side of the non-display area 122. The data driver 175 may be mounted on the display panel 110 by a chip-on-glass manner or connected to the display panel 110 by a chip-on-film manner, so that the data driver 175 may be located on the outermost area of the drivers placement area 125. The gate driver 180 may be located on the innermost area of the drivers placement area 125, as illustrated in FIG. 1. In some example embodiments, however, the light emission control driver 185 may be located on the innermost area of the drivers placement area 125. Here, the organic light emitting display device 100 may have a structure in which drivers may not be located at 3 sides of the display panel 110, so that a dead space may be reduced on the 3 sides of the display panel 110.

In another example embodiment, the drivers placement area 125 may be at both sides of the non-display area 122 in the first direction. In other words, each of the data driver 175, the gate driver 180, and the light emission control driver 185 may be located at one of the both sides of the non-display area 122. Here, the organic light emitting display device 100 may have a structure in which drivers may not be located at 2 sides of the display panel 110, so that a dead space may be reduced on the 2 sides of the display panel 110.

The data lines 160 may extend in the first direction on the display area 120.

The data lines 160 may be connected to the data driver 175 located at the drivers placement area 125. The data lines 160 may be connected to corresponding pixels PX to transfer the data signal DT.

The gate lines 140 may extend in a second direction substantially perpendicular to the first direction on the display area 120. For example, as illustrated in FIG. 1, the second direction may be a left-and-right direction of the display panel 110. The gate lines 140 may be connected to corresponding pixels PX to sequentially transfer the gate signal GW row by row.

The initialization control lines 145 may extend in the second direction on the display area 120. The initialization control lines 145 may be connected to corresponding pixels PX to sequentially transfer the initialization control signal GI row by row.

The light emission control line's 150 may extend in the second direction on the display area 120. The light emission control lines 150 may be connected to corresponding pixels PX to sequentially transfer the light emission control signal EM row by row.

The bypass control lines 155 may extend in the second direction on the display area 120. The bypass control lines 155 may be connected to corresponding pixels PX to sequentially transfer the bypass control signal GB row by row. In some example embodiments, the bypass control lines 155 may not be used according to a structure of a pixel circuit included in the pixels PX.

The driving control signal supplying lines 165 may extend in the first direction on the display area 120. The driving control signal supplying lines 165 may be connected to the gate driver 180 located at the drivers placement area 125. The driving control signal supplying line 165 may be connected to the gate line 140, the initialization control line 145, and the bypass control line 155. The driving control signal supplying line 165 may transfer the driving control signal DC including at least one of the gate signal GW, the initialization signal GI, and the bypass control signal GB. In other words, the driving control signal supplying line 165 may transfer the driving control signal DC that serves as at least one of the gate signal GW, the initialization control signal GI, and the bypass control signal GB. In some example embodiments, the driving control signal supplying lines 165 may be connected to the gate line 140, the initialization control line 145, and the bypass control line 155 through a contact hole. Because the gate driver 180 is located at the drivers placement area 125 located outside the display area 120 in the first direction, the gate driver 180 may not be directly connected to the gate lines 140, the initialization control lines 145, and the bypass control lines 155 extending in the second direction. Therefore, the driving control signal supplying lines 165 extending in the first direction may be connected to the gate driver 180, and the gate driver 180 may be connected to the gate lines 140, the initialization control lines 145, and the bypass control lines 155 through the driving control signal supplying lines 165.

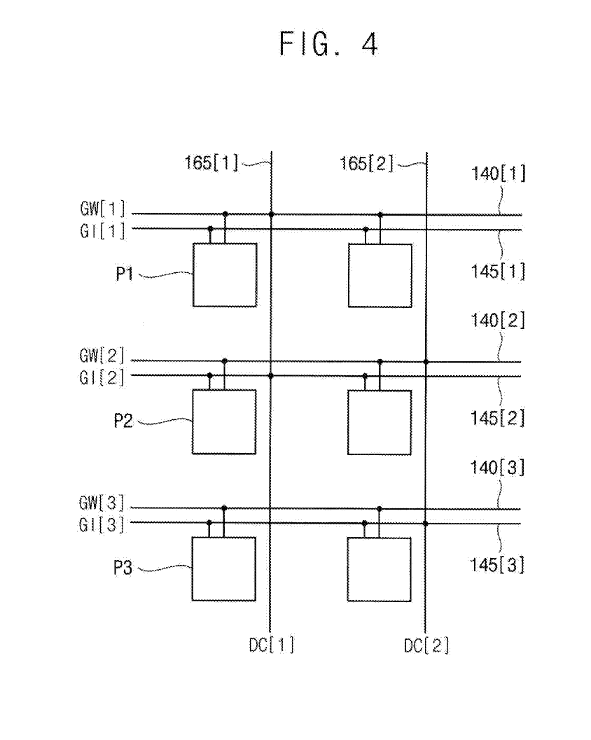

In an example embodiment, the driving control signal supplying line 165 may be connected to at least one of the gate lines 140 and at least one of the initialization control lines 145. Here, the driving control signal DC supplied through the driving control signal supplying line 165 may include the gate signal GW and the initialization control signal GI. In other words, the driving control signal DC may serve as the gate signal GW and the initialization control signal GI. An example in which the gate lines 140 and the initialization control lines 145 are connected to the driving control signal supplying lines 165 will be described in detail with reference to FIG. 4.

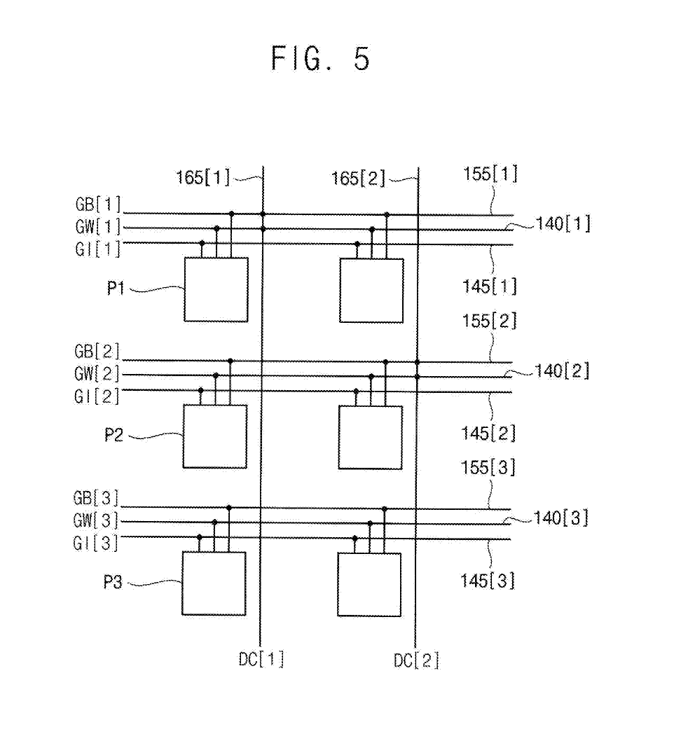

In another example embodiment, the driving control signal supplying line 165 may be connected to at least one of the gate lines 140 and at least one of the bypass control lines 155. Here, the driving control signal DC supplied through the driving control signal supplying line 165 may include the gate signal GW and the bypass control signal GB. In other words, the driving control signal DC may serve as the gate signal GW and the bypass control signal GB. An example in which the gate lines 140 and the bypass control lines 155 are connected to the driving control signal supplying lines 165 will be described in detail with reference to FIG. 5.

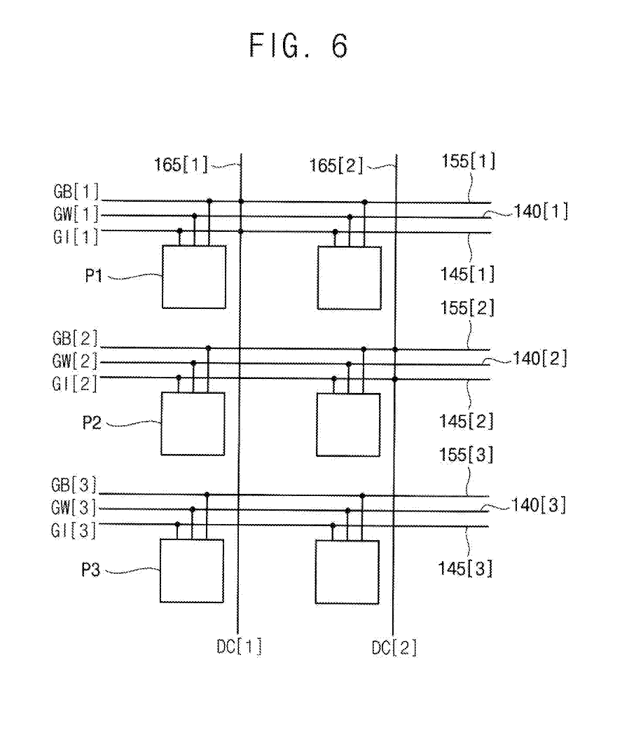

In still another example embodiment, the driving control signal supplying line 165 may be connected to at least one of the initialization control lines 145 and at least one of the bypass control lines 155. Here, the driving control signal DC supplied through the driving control signal supplying line 165 may include the initialization control signal GI and the bypass control signal GB. In other words, the driving control signal DC may serve as the initialization control signal GI and the bypass control signal GB. An example in which the initialization control lines 145 and the bypass control lines 155 are connected to the driving control signal supplying lines 165 will be described in detail with reference to FIG. 6.

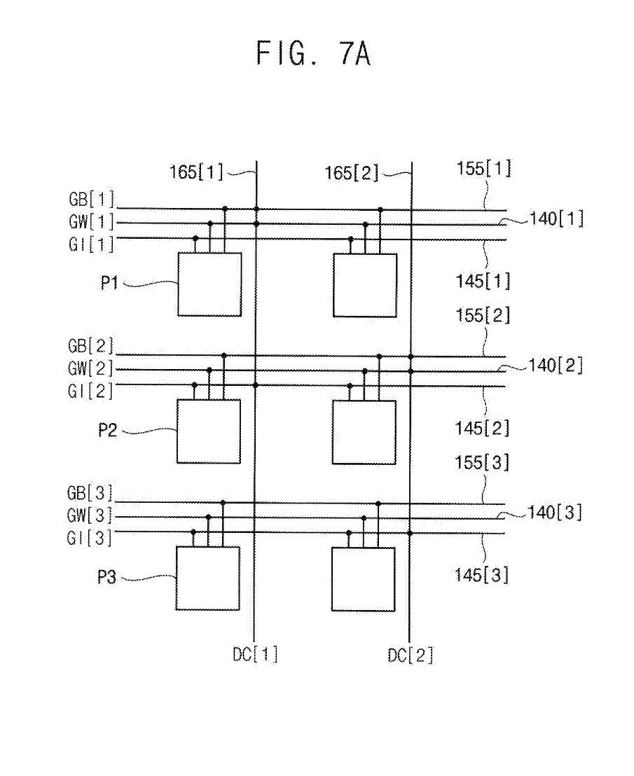

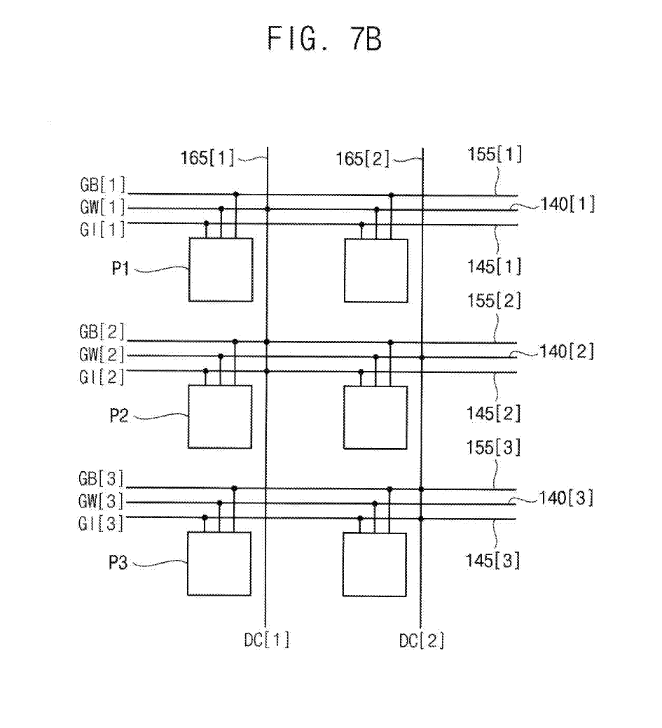

In still another example embodiment, the driving control signal supplying line 165 may be connected to at least one of the gate lines 140, at least one of the initialization control lines 145, and at least one of the bypass control lines 155. Here, the driving control signal DC supplied through the driving control signal supplying line 165 may include the gate signal GW, the initialization control signal GI, and the bypass control signal GB. In other words, the driving control signal DC may serve as the gate signal GI, the initialization control signal GI, and the bypass control signal GB. Examples in which the gate lines 140, the initialization control lines 145, and the bypass control lines 155 are connected to the driving control signal supplying lines 165 will be described in detail with reference to FIGS. 7A and 7B.

The light emission control signal supplying lines 170 may extend in the first direction on the display area 120. The light emission control signal supplying lines 170 may be connected to the light emission control driver 185 located at the drivers placement area 125. The light emission control signal supplying line 170 may be connected to the light emission control line 150 to transfer the light emission control signal EM. In some example embodiments, the light emission control signal supplying lines 170 may be connected to the light emission control line 150 through a contact hole. Because the light emission control driver 185 is located at the drivers placement area 125 located outside the display area 120 in the first direction, the light emission control driver 185 may not be directly connected to the light emission control lines 150 extending in the second direction. Therefore, the light emission control signal supplying lines 170 extending in the first direction may be connected to the light emission control driver 185, and the light emission control driver 185 may be connected to the light emission control lines 150 through the light emission control signal supplying lines 170.

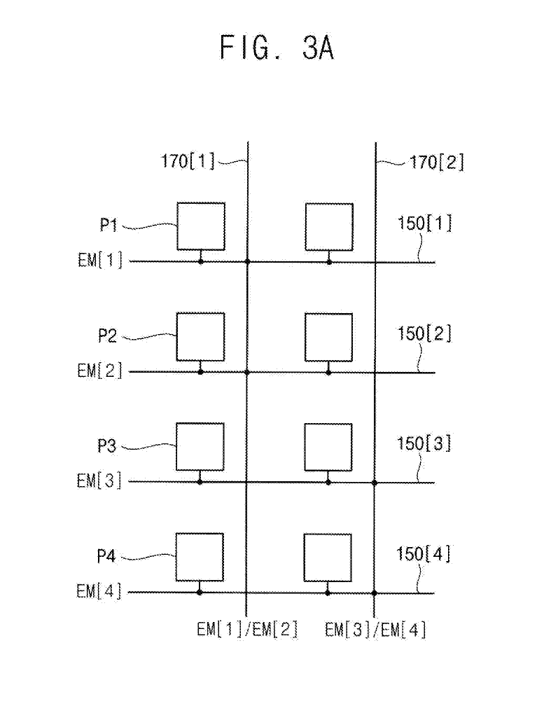

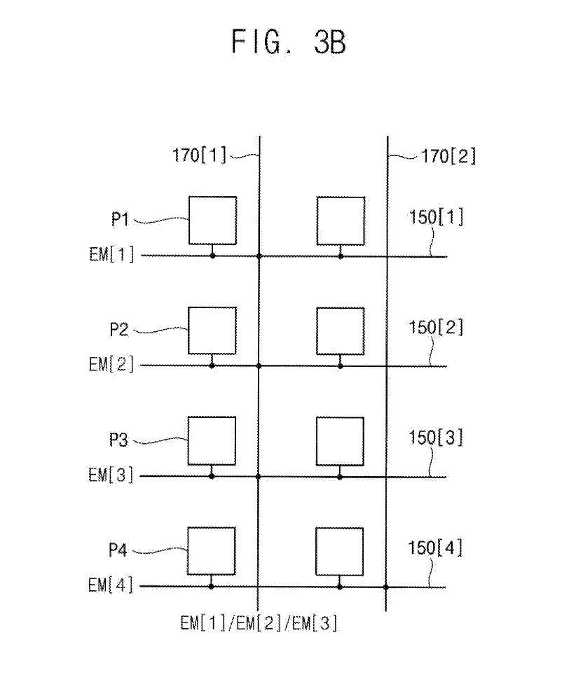

In some example embodiments, the light emission control signal supplying line 170 may be connected to at least two of the light emission control lines 150. The at least two of the light emission control lines 150 connected to the light emission control signal supplying line 170 may receive the same light emission control signal EM. As the number of the light emission control lines 150 connected to the same light emission control supplying line 170 increases, the number of the light emission control supplying lines 170 located at the display area 120 decreases, so that an area occupied by the light emission control signal supplying lines 170 may be reduced. Examples in which the light emission control lines 150 are connected to the light emission control signal supplying lines 170 will be described in detail with reference to FIGS. 3A and 3B.

Power voltage lines and initialization voltage lines extending in the first direction or in the second direction may be located at the display area 120. The power voltage lines and the initialization voltage lines may be connected to the pixels PX. Here, the power voltage lines may transfer a first power voltage ELVDD and the initialization voltage lines may transfer an initialization voltage VINIT.

FIGS. 3A and 3B are diagrams illustrating examples in which light emission control lines are connected to light emission control signal supplying lines in the organic light emitting display device of FIG. 1.

Referring to FIGS. 3A and 3B, the organic light emitting display device 100 may include a first pixel P1, a second pixel P2, a third pixel P3, a fourth pixel P4, a first light emission control line 150[1], a second light emission control line 150[2], a third light emission control line 150[3], a fourth light emission control line 150[4], a first light emission control signal supplying line 170[1], and a second light emission control signal supplying line 170[2].

The first to fourth pixels P1 to P4 may be pixels disposed in the first direction on the display area 120. For example, when the first pixel P1 is located at a k-th row, the second pixel P2 may be located at a (k+1)-th row, the third pixel P3 may be located at a (k+2)-th row, and the fourth pixel P4 may be located at a (k+3)-th row, where k is a positive integer less than or equal to (N−3). The first to fourth light emission control lines 150[1] to 150[4] may extend in the second direction on the display area 120 and may be connected to the first to fourth pixels P1 to P4, respectively.

The first and second light emission control signal supplying lines 170[1] and 170[2] may extend in the first direction on the display area 120. The first and second light emission control signal supplying lines 170[1] and 170[2] may be connected to the light emission control driver 185 to receive the light emission control signal EM.

As illustrated in FIG. 3A, in an example embodiment, the light emission control signal supplying line 170 may be connected to two light emission control lines 150. For example, the first light emission control signal supplying line 170[1] may be connected to the first light emission control line 150[1] and the second light emission control line 150[2], and the second light emission control signal supplying line 170[2] may be connected to the third light emission control line 150[3] and the fourth light emission control line 150[4]. Here, the light emission control signal EM[1]/EM[2] transferred through the first light emission control signal supplying line 170[1] may be transferred to the first pixel P1 through the first light emission control line 150[1], and may be transferred to the second pixel P2 through the second light emission control line 150[2]. In other words, the light emission control signal EM[1]/EM[2] transferred through the first light emission control signal supplying line 170[1] may serve as the first light emission control signal EM[1] and the second light emission control signal EM[2]. Therefore, because one light emission control signal supplying line 170 is used to transfer the light emission control signal EM to two pixels PX instead of using two light emission control signal supplying lines 170, an area occupied by the light emission control signal supplying lines 170 on the display area 120 may be substantially reduced to about half.

As illustrated in FIG. 3B, in another example embodiment, the light emission control signal supplying line 170 may be connected to three light emission control lines 150. For example, the first light emission control signal supplying line 170[1] may be connected to the first light emission control line 150[1], the second light emission control line 150[2], and the third light emission control line 150[3]. Here, the light emission control signal EM[1]/EM[2]/EM[3] transferred through the first light emission control signal supplying line 170[1] may be transferred to the first pixel P1 through the first light emission control line 150[1], may be transferred to the second pixel P2 through the second light emission control line 150[2], and may be transferred to the third pixel P3 through the third light emission control line 150[2]. In other words, the light emission control signal EM[1]/EM[2]/EM[3] transferred through the first light emission control signal supplying line 170[1] may serve as the first light emission control signal EM[1], the second light emission control signal EM[2], and the third light emission control signal EM[3]. Therefore, because one light emission control signal supplying line 170 is used to transfer the light emission control signal EM to three pixels PX instead of using three light emission control signal supplying lines 170, an area occupied by the light emission control signal supplying lines 170 on the display area 120 may be substantially reduced to about one-third.

FIG. 4 is a diagram illustrating an example in which gate lines and initialization control lines are connected to driving control signal supplying lines in the organic light emitting display device of FIG. 1.

Referring to FIG. 4, the organic light emitting display device 100 may include a first pixel P1, a second pixel P2, a third pixel P3, a first gate line 140[1], a second gate line 140[2], a third gate line 140[3], a first initialization control line 145[1], a second initialization control line 145[2], a third initialization control line 145[3], a first driving control signal supplying line 165[1], and a second driving control signal supplying line 165[2]. Detailed description of elements (or components) in FIG. 4 which are substantially the same as or similar to those illustrated with reference to previous figures (e.g., FIG. 3A) may not be repeated.

The first to third gate lines 140[1] to 140[3] may extend in the second direction on the display area 120, and may be connected to the first to third pixels P1 to P3, respectively.

The first to third initialization control lines 145[1] to 145[3] may extend in the second direction on the display area 120, and may be connected to the first to third pixels P1 to P3, respectively.

The first and second driving control signal supplying lines 165[1] and 165[2] may extend in the first direction, may be connected to the gate driver 180 to receive the driving control signal DC.

In some example embodiments, the first driving control signal supplying line 165[1] may be connected to the first gate line 140[1] and the second initialization control line 145[2], and the second driving control signal supplying line 165[2] may be connected to the second gate line 140[2] and the third initialization control line 145[3]. Here, the first driving control signal DC[1] transferred through the first driving control signal supplying line 165[1] may be transferred to the first pixel P1 through the first gate line 140[1], and may be transferred to the second pixel P2 through the second initialization control line 145[2]. In other words, the first driving control signal DC[1] may serve as the first gate signal GW[1] and the second initialization control signal GI[2]. Therefore, because one driving control signal supplying line 165 is used to transfer the gate signal GW and the initialization control signal GI to two pixels PX, respectively instead of using two driving control signal supplying lines 165, an area occupied by the driving control signal supplying lines 165 on the display area 120 may be substantially reduced to about half. Moreover, because the first driving control signal DC[1] includes the first gate signal GW[1] and the second initialization control signal GI[2], an area of the gate driver 180 may be reduced. Therefore, an area of the drivers placement area 125 may be reduced, and a dead space of the display panel 110 may be reduced.

As illustrated in FIG. 4, when the first pixel P1 is included in the first pixel row in the first direction, the first initialization control line 145[1] may not be connected to the driving control signal supplying line 165, and may not receive the first initialization control signal GI[1]. Therefore, the first pixel P1 may be a dummy pixel which does not operate to display an image, and thus the first pixel row including the first pixel P1 may be referred to as a dummy pixel row. As illustrated in FIG. 4, when the third pixel P3 is included in the last pixel row in the first direction, the third gate line 140[3] may not be connected to the driving control signal supplying line 165, and may not receive the third gate signal GW[3]. Therefore, the third pixel P3 may be a dummy pixel which does not operate to display an image, and thus the last pixel row including the third pixel P3 may be referred to as a dummy pixel row.

FIG. 5 is a diagram illustrating an example in which gate lines and bypass control lines are connected to driving control signal supplying lines in the organic light emitting display device of FIG. 1. FIG. 6 is a diagram illustrating an example in which initialization control lines and bypass control lines are connected to driving control signal supplying lines in the organic light emitting display device of FIG. 1. FIGS. 7A and 7B are diagrams illustrating examples in which gate lines, initialization control lines, and bypass control lines are connected to driving control signal supplying lines in the organic light emitting display device of FIG. 1.

Referring to FIGS. 5 to 7B, the organic light emitting display device 100 may include a first pixel P1, a second pixel P2, a third pixel P3, a first gate line 140[1], a second gate line 140[2], a third gate line 140[3], a first initialization control line 145[1], a second initialization control line 145[2], a third initialization control line 145[3], a first bypass control line 155[1], a second bypass control line 155[2], a third bypass control line 155[3], a first driving control signal supplying line 165[1], and a second driving control signal supplying line 165[2]. Detailed description of elements (or components) in

FIGS. 5 to 7B which are substantially the same as or similar to those illustrated with reference to previous figures (e.g., FIG. 4) may not be repeated.

The first to third bypass control lines 155[1] to 155[3] may extend in the second direction on the display area 120, and may be connected to the first to third pixels P1 to P3, respectively.

As illustrated in FIG. 5, in an example embodiment, the first driving control signal supplying line 165[1] may be connected to the first gate line 140[1] and the first bypass control line 155[1], and the second driving control signal supplying line 165[2] may be connected to the second gate line 140[2] and the second bypass control line 155[2]. Here, the first driving control signal DC[1] transferred through the first driving control signal supplying line 165[1] may be transferred to the first pixel P1 through the first gate line 140[1], and may be transferred to the first pixel P1 through the first bypass control line 155[1]. In other words, the first driving control signal DC[1] may serve as the first gate signal GW[1] and the first bypass control signal GB[1]. Therefore, because one driving control signal supplying line 165 is used to transfer the gate signal GW and the bypass control signal GB to one pixel PX instead of using two driving control signal supplying lines 165, an area occupied by the driving control signal supplying lines 165 on the display area 120 may be substantially reduced to about half. Moreover, because the first driving control signal DC[1] includes the first gate signal GW[1] and the first bypass control signal GB[1 ], an area of the gate driver 180 may be reduced. Therefore, an area of the drivers placement area 125 may be reduced, and a dead space of the display panel 110 may be reduced.

As illustrated in FIG. 6, in another example embodiment, the first driving control signal supplying line 165[1] may be connected to the first initialization control line 145[1] and the first bypass control line 155[1], and the second driving control signal supplying line 165[2] may be connected to the second initialization control line 145[2] and the second bypass control line 155[2]. Here, the first driving control signal DC[1] transferred through the first driving control signal supplying line 165[1] may be transferred to the first pixel P1 through the first initialization control line 145[1], and .may be transferred to the first pixel P1 through the first bypass control line 155[1]. In other words, the first driving control signal DC[1] may serve as the first initialization control signal GI[1] and the first bypass control signal GB[1]. Therefore, because one driving control signal supplying line 165 is used to transfer the initialization control signal GI and the bypass control signal GB to one pixel PX instead of using two driving control signal supplying lines 165, an area occupied by the driving control signal supplying lines 165 on the display area 120 may be substantially reduced to about half. Moreover, because the first driving control signal DC[1] includes the first initialization control signal GI[1] and the first bypass control signal GB[1], an area of the gate driver 180 may be reduced. Therefore, an area of the drivers placement area 125 may be reduced, and a dead space of the display panel 110 may be reduced.

As illustrated in FIG. 7A, in still another example embodiment, the first driving control signal supplying line 165[1] may be connected to the first gate line 140[1], the second initialization control line 145[2], and the first bypass control line 155[1], and the second driving control signal supplying line 165[2] may be connected to the second gate line 140[2], the third initialization control line 145[3], and the second bypass control line 155[2]. Here, the first driving control signal DC[1] transferred through the first driving control signal supplying line 165[1] may be transferred to the first pixel P1 through the first gate line 140[1], may be transferred to the second pixel P2 through the second initialization control line 145[2], and may be transferred to the first pixel P1 through the first bypass control line 155[1]. In other words, the first driving control signal DC[1] may serve as the first gate signal GW[1], the second initialization control signal GI[2], and the first bypass control signal GB[1]. Therefore, because one driving control signal supplying line 165 is used to transfer the gate signal GW and the bypass control signal GB to one pixel PX and to transfer the initialization control signal GI to the other pixel PX instead of using three driving control signal supplying lines 165, an area occupied by the driving control signal supplying lines 165 occupy on the display area 120 may be substantially reduced to about one-third. Moreover, because the first driving control signal DC[1] includes the first gate signal GW[1], the second initialization control signal GI[2], and the first bypass control signal GB[1], an area of the gate driver 180 may be reduced. Therefore, an area of the drivers placement area 125 may be reduced, and a dead space of the display panel 110 may be reduced.

As illustrated in FIG. 7B, in still another example embodiment, the first driving control signal supplying line 165[1] may be connected to the first gate line 140[1], the second initialization control line 145[2], and the second bypass control line 155[2], and the second driving control signal supplying line 165[2] may be connected to the second gate line 140[2], the third initialization control line 145[3], and the third bypass control line 155[3]. Here, the first driving control signal DC[1] transferred through the first driving control signal supplying line 165[1] may be transferred to the first pixel P1 through the first gate line 140[1], may be transferred to the second pixel P2 through the second initialization control line 145[2], and may be transferred to the second pixel P2 through the second bypass control line 155[2]. In other words, the first driving control signal DC[1] may serve as the first gate signal GW[1], the second initialization control signal GI[2], and the second bypass control signal GB[2]. Therefore, because one driving control signal supplying line 165 is used to transfer the initialization control signal GI and the bypass control signal GB to one pixel PX and to transfer the gate signal GW to the other pixel PX instead of using three driving control signal supplying lines 165, an area occupied by the driving control signal supplying lines 165 on the display area 120 may be substantially reduced to about one-third. Moreover, because the first driving control signal DC[1] includes the first gate signal GW[1], the second initialization control signal GI[2], and the second bypass control signal GB[2], an area of the gate driver 180 may be reduced. Therefore, an area of the drivers placement area 125 may be reduced, and a dead space of the display panel 110 may be reduced.

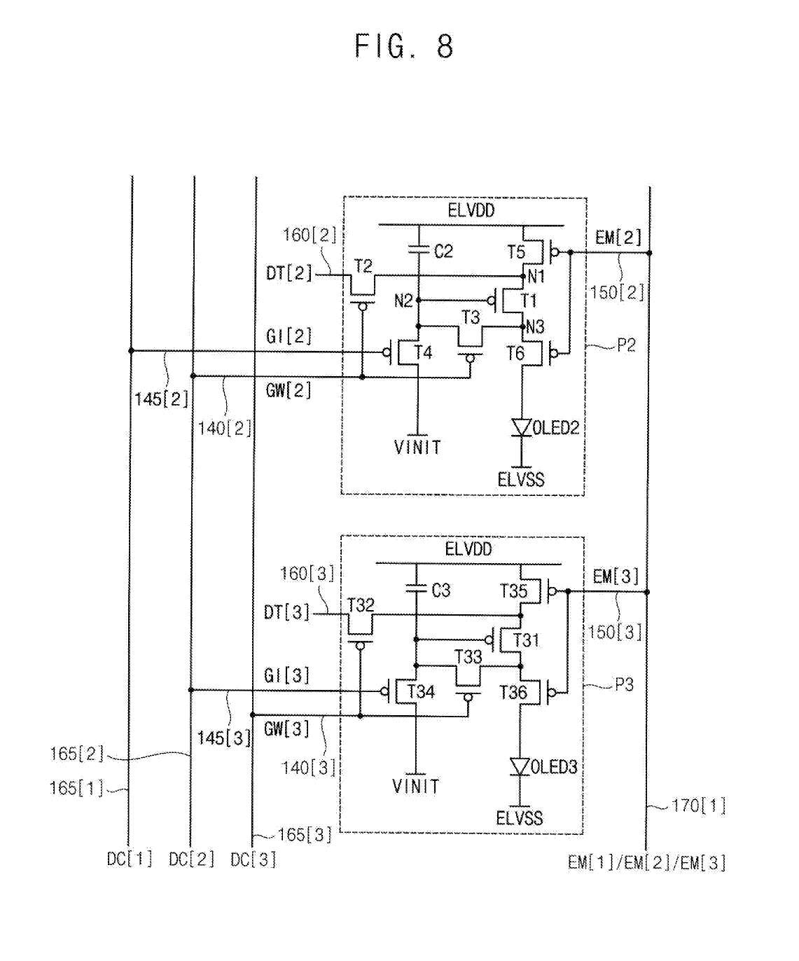

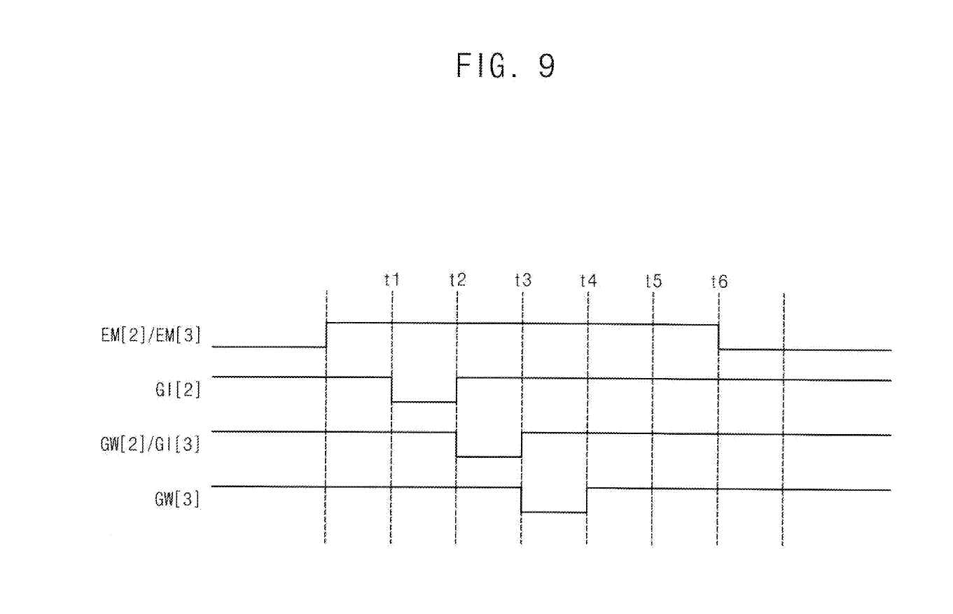

FIG. 8 is a circuit diagram illustrating an example of a pixel included in the organic light emitting display device of FIG. 1. FIG. 9 is a timing diagram for illustrating a method of driving the pixel of FIG. 8.

Referring to FIGS. 8 and 9, each of a first pixel P1, a second pixel P2, and a third pixel P3 may include an organic light emitting diode that emits light and a pixel circuit that drives the organic light emitting diode. Elements (or components) of the first pixel P1 are not illustrated in FIG. 8. However, the elements (or components) of the first pixel P1 are substantially the same as the second pixel P2 and the third pixel P3. In some example embodiments, the pixel circuit may include six thin film transistors and one capacitor.

The first pixel P1 may be connected to a first gate line 140[1], a first initialization control line 145[1], a first light emission control line 150[1], and a first data line 160[1]. The second pixel P2 may be connected to a second gate line 140[2], a second initialization control line 145[2], a second light emission control line 150[2], and a second data line 160[2]. The third pixel P3 may be connected to a third gate line 140[3], a third initialization control line 145[3], a third light emission control line 150[3], and a third data line 160[3].

The first light emission control line 150[1], the second light emission control line 150[2], and the third light emission control line 150[3] are connected to the first light emission control signal supplying line 170[1] as shown in FIG. 3B. The first gate line 140[1] and second initialization control line 145[2] are connected to the first driving control signal supplying line 165[1], the second gate line 140[2] and the third initialization control line 145[3] are connected to the second driving control signal supplying line 165[2], and the third gate line 140[3] is connected to the third driving control signal supplying line 165[3] as shown in FIG. 4. However, connections of the lines are not limited thereto.

Because elements (or components) of the first pixel P1, the second pixel P2, and the third pixel P3 are substantially the same, the second pixel P2 will be used to describe the elements (or components) of the pixel PX.

The second pixel P2 may include a driving thin film transistor T1, a switching thin film transistor T2, a compensation thin film transistor T3, an initialization thin film transistor T4, a first light emission control thin film transistor T5, and a second light emission control thin film transistor T6.

The driving thin film transistor T1 may include a source electrode connected to a first node N1, a gate electrode connected to a second node N2, and a drain electrode connected to a third node N3. The driving thin film transistor T1 may control a driving current passing through the third node N3 based on voltage applied to the gate electrode.

The switching thin film transistor T2 may include a first electrode connected to the second data line 160[2], a second electrode connected to the first node N1, and a gate electrode connected to the second gate line 140[2]. The switching thin film transistor T2 may be turned-on based on a second gate signal GW[2] and may transfer a second data signal DT[2] to the first node NI.

The compensation thin film transistor T3 may include a first electrode connected to the second node N2, a second electrode connected to the third node N3, and a gate electrode connected to the second gate line 140[2]. The compensation thin film transistor T3 may be turned-on based on the second gate signal GW[2] and may diode-connect the drain electrode and the gate electrode of the driving thin film transistor T1.

The initialization thin film transistor T4 may include a first electrode connected to the second node N2, a second electrode receiving an initialization voltage VINIT, and a gate electrode connected to the second initialization control line 145[2].

The first light emission control thin film transistor T5 may include a first electrode receiving a first power voltage ELVDD, a second electrode connected to the first node N1, and a gate electrode connected to the second light emission control line 150[2].

The second light emission control thin film transistor T6 may include a first electrode connected to the third node N3, a second electrode connected to an anode electrode of an organic light emitting diode OLED2, and a gate electrode connected to the second light emission control line 150[2].

A cathode electrode of the organic light emitting diode OLED2 may receive a second power voltage ELVSS. A capacitor C2 may include a first electrode receiving the first power voltage ELVDD and a second electrode connected to the second node N2. The capacitor C2 may store a voltage value reflecting a threshold voltage of the driving thin film transistor T1.

As described above, the second light emission control signal EM[2], the second initialization control signal GI[2], and the second gate signal GW[2] are applied to the second pixel P2, and the third light emission control signal EM[3], the third initialization control signal GI[3], and the third gate signal GW[3] are applied to the third pixel P3.

As illustrated in FIG. 9, a low-level second initialization control signal GI[2] may be applied to the second pixel P2 through the second initialization control line 145[2] at a first timing t1. Then, the initialization thin film transistor T4 of the second pixel P2 may be turned-on based on the low-level second initialization control signal GI[2], and the driving thin film transistor T1 of the second pixel P2 may be initialized by the initialization voltage VINIT.

Then, a low-level second gate signal GW[2] may be applied to the second pixel P2 through the second gate line 140[2] at a second timing t2. Then, the switching thin film transistor T2 and the compensation thin film transistor T3 of the second pixel P2 may be turned-on based on the low-level second gate signal GW[2].

Here, a compensation voltage that is obtained by subtracting the threshold voltage of the driving thin film transistor T1 of the second pixel P2 from a voltage corresponding to the second data signal DT[2] may be applied to the driving thin film transistor T1 of the second pixel P2.

A low-level third initialization control signal GI[3] may be applied to the third pixel P3 through the third control line 145[3] at the second timing t2. Then, an initialization thin film transistor T34 of the third pixel P3 may be turned-on based on the low-level third initialization control signal GI[3], and a driving thin film transistor T31 of the third pixel P3 may be initialized by the initialization voltage VINIT.

Then, a low-level third gate signal GW[3] may be applied to the third pixel P3 through the third gate line 140[3] at a third timing t3. Then, a switching thin film transistor T32 and a compensation thin film transistor T33 of the third pixel P3 may be turned-on based on the low-level third gate signal GW[3].

Here, a compensation voltage that is obtained by subtracting the threshold voltage of the driving thin film transistor T31 of the third pixel P3 from a voltage corresponding to the third data signal DT[3] may be applied to the driving thin film transistor T31 of the third pixel P3.

Then, at a sixth timing t6, a low-level second light emission control signal EM[2] may be applied to the second pixel P2 through the second light emission control line 150[2], and a low-level third light emission control signal EM[3] may be applied to the third pixel P3 through the third light emission control line 150[3]. Then, the first light emission control thin film transistor T5 and the second light emission control thin film transistor T6 of the second pixel P2 may be turned-on based on the low-level second light emission control signal EM[2], and a first light emission control thin film transistor T35 and a second light emission control thin film transistor T36 of the third pixel P3 may be turned-on based on the low-level third light emission control signal EM[3].

Here, the driving current that corresponds to a voltage difference between a voltage of the gate electrode of the driving thin film transistor T1 of the second pixel P2 and the first power voltage ELVDD may be generated, and the driving current may be applied to the organic light emitting diode OLED2 of the second pixel P2. In addition, the driving current that corresponds to a voltage difference between a voltage of the gate electrode of the driving thin film transistor T31 of the third pixel P3 and the first power voltage ELVDD may be generated, and the driving current may be applied to the organic light emitting diode OLED3 of the third pixel P3. Then, each of the organic light emitting diodes OLED2 and OLED3 may emit light corresponding to the driving current.

As described above, the second light emission control line 150[2] and the third light emission control line 150[3] may be connected to the first light emission control signal supplying line 170[1] and may supply substantially the same light emitting control signal EM[2]/EM[3] to the second pixel P2 and the third pixel P3. In addition, the second gate signal GW[2] and the third initialization control signal GI[3] may be substantially the same because the second gate line 140[2] and the third initialization control line 145[3] are connected to the second driving control signal supplying line 165[2]. Here, the second pixel P2 and the third pixel P3 may emit light corresponding to the second data signal DT[2] and the third data signal DT[3], respectively. Thus, the second and third pixels P2 and P3 may operate to display an image.

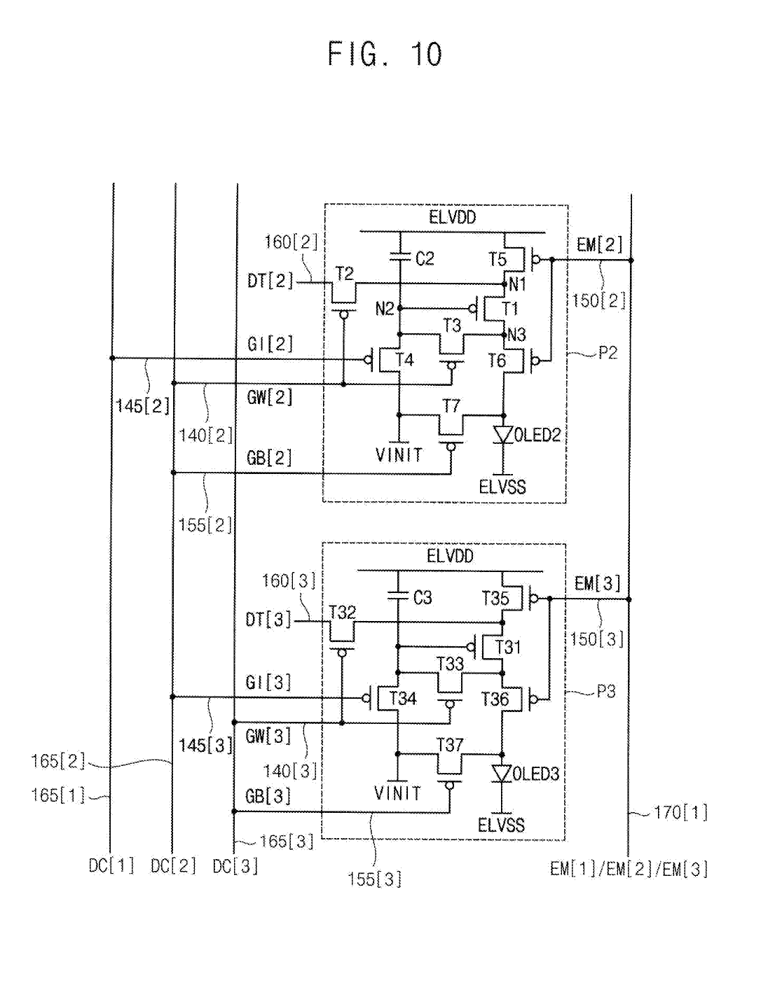

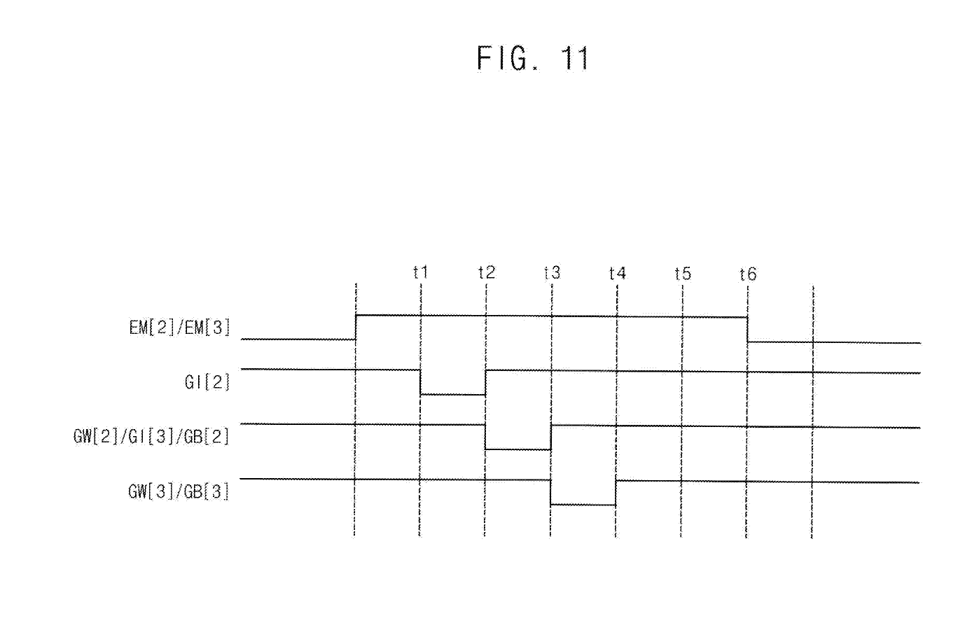

FIG. 10 is a circuit diagram illustrating another example of a pixel included in the organic light emitting display device of FIG. 1. FIG. 11 is a timing diagram for illustrating a method of driving the pixel of FIG. 10.

Referring to FIGS. 10 and 11, each of a first pixel P1, a second pixel P2, and a third pixel P3 may include an organic light emitting diode that emits light and a pixel circuit that drives the organic light emitting diode. Elements (or components) of the first pixel P1 are not illustrated in FIG. 10. However, the elements (or components) of the first pixel P1 are substantially the same as the second pixel P2 and the third pixel P3. In some example embodiments, the pixel circuit may include seven thin film transistors and one capacitor. Detailed description of elements (or components) in FIGS. 10 and 11 which are substantially the same as or similar to those illustrated with reference to previous figures (e.g., FIGS. 8 and 9) may not be repeated.

The first pixel P1 may be connected to a first gate line 140[1], a first initialization control line 145[1], a first light emission control line 150[1], a first bypass control line 155[1], and a first data line 160[1]. The second pixel P2 may be connected to a second gate line 140[2], a second initialization control line 145[2], a second light emission control line 150[2], a second bypass control line 155[2], and a second data line 160[2]. The third pixel P3 may be connected to a third gate line 140[3], a third initialization control line 145[3], a third light emission control line 150[3], a third bypass control line 155[3], and a third data line 160[3].

The first light emission control line 150111, the second light emission control line 150[2], and the third light emission control line 150[3] are connected to the first light emission control signal supplying line 170[1] as shown in FIG. 3B. The first gate line 140[1], the first bypass control line 155[1], and second initialization control line 145[2] are connected to the first driving control signal supplying line 165[1], the second gate line 140[2], the second bypass control line 155[2], and the third initialization control line 145[3] are connected to the second driving control signal supplying line 165[2], and the third gate line 140[3] and the third bypass control line 155[3] are connected to the third driving control signal supplying line 165[3] as shown in FIG. 7A. However, connections of the lines are not limited thereto.

The second pixel P2 may include a driving thin film transistor T1, a switching thin film transistor T2, a compensation thin film transistor T3, an initialization thin film transistor T4, a first light emission control thin film transistor T5, a second light emission control thin film transistor T6, and a bypass thin film transistor T7.

The bypass thin film transistor T7 may include a first electrode connected to an anode electrode of an organic light emitting diode OLED2, a second electrode connected to a second electrode of the initialization thin film transistor T4, and a gate electrode connected to the second bypass control line 155[2].

As described above, the second light emission control signal EM[2], the second initialization control signal GI[2], the second gate signal GW[2], and the second bypass control signal GB[2] are applied to the second pixel P2, and the third light emission control signal EM[3], the third initialization control signal GI[3], the third gate signal GW[3], and the third bypass control signal GB[3] are applied to the third pixel P3.

As illustrated in FIG. 11, a low-level second bypass control signal GB[2] may be applied to the second pixel P2 through the second bypass control line 155[2] at a second timing t2. Then, the bypass thin film transistor T7 of the second pixel P2 may be turned-on based on the low-level second bypass control signal GB[2].

Here, a leakage current of the driving thin film transistor T1 of the second pixel P2 may be discharged through the bypass thin film transistor T7 of the second pixel P2.

Then, a low-level third bypass control signal GB[3] may be applied to the third pixel P3 through the third bypass control line 155[3] at a third timing t3. Then, the bypass thin film transistor T37 of the third pixel P3 may be turned-on based on the low-level third bypass control signal GB[3].

Here, a leakage current of the driving thin film transistor T31 of the third pixel P3 may be discharged through the bypass thin film transistor T37 of the third pixel P3.

As described above, the second light emission control line 150[2] and the third light emission control line 150[3] may be connected to the first light emission control signal supplying line 170[1] and may supply substantially the same light emitting control signal EM[2]/EM[3] to the second pixel P2 and the third pixel P3. In addition, the second gate signal GW[2], the second bypass control signal GB[2], and the third initialization control signal GI[3] may be substantially the same because the second gate line 140[2], the second bypass control line 155[2], and the third initialization control line 145[3] are connected to the second driving control signal supplying line 165[2]. Here, the second pixel P2 and the third pixel P3 may emit light corresponding to the second data signal DT[2] and the third data signal DT[3], respectively. Thus, the second and third pixels P2 and P3 may operate to display an image.

Although organic light emitting display devices according to example embodiments have been described with reference to FIGS. 1 to 11, those skilled in the art will readily appreciate that many modifications are possible in the example embodiments without materially departing from the novel teachings and advantages of the present inventive concept. For example, although it is illustrated above that thin film transistors included in a pixel circuit are p-channel metal oxide semiconductor (PMOS) transistors, types of the thin film transistors included in the pixel circuit are not limited thereto. That is, the thin film transistors included in the pixel circuit may be n-channel metal oxide semiconductor (NMOS) transistors or complementary metal oxide semiconductor (CMOS) transistors.

Embodiments of the present inventive concept may be applied to any electronic device including a display device. For example, embodiments of the present inventive concept may be applied to display devices for computers, notebooks, cellular phones, smart phones, smart pads, portable media players (PMPs), personal digital assistances (PDAs), MP3 players, digital cameras, video camcorders, etc.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such suitable modifications are intended to be included within the scope of the present inventive concept as defined in the claims and their equivalents. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. An organic light emitting display device, comprising:
a first pixel, a second pixel, and a third pixel arranged in a first direction on a display area of a display panel;
a data line connected to the first pixel, the second pixel, and the third pixel and extending in the first direction on the display area;
a first gate line, a second gate line, and a third gate line respectively connected to the first pixel, the second pixel, and the third pixel and extending in a second direction perpendicular to the first direction on the display area;
a first initialization control line, a second initialization control line, and a third initialization control line respectively connected to the first pixel, the second pixel and the third pixel and extending in the second direction on the display area;
a first light emission control line, a second light emission control line, and a third light emission control line respectively connected to the first pixel, the second pixel, and the third pixel and extending in the second direction on the display area;
a driving control signal supplying line connected to at least one of the first gate line, the second gate line, and the third gate line and at least one of the first initialization control line, the second initialization control line, and the third initialization control line and extending in the first direction on the display area;
a light emission control signal supplying line connected to at least two of the first light emission control line, the second light emission control line, and the third light emission control line and extending in the first direction on the display area;
a data driver connected to the data line, configured to supply a data signal, and located at a drivers placement area, the drivers placement area being located outside the display area in the first direction and included in a non-display area;
a gate driver connected to the driving control signal supplying line, configured to supply a driving control signal, and located at the drivers placement area; and
a light emission control driver connected to the light emission control signal supplying line, configured to supply a light emission control signal, and located at the drivers placement area.

2. The display device of claim 1,
wherein the light emission control signal supplying line is connected to the first light emission control line and the second light emission control line.

3. The display device of claim 1,
wherein the light emission control signal supplying line is connected to the first light emission control line, the second light emission control line, and the third light emission control line.

4. The display device of claim 1,
wherein the driving control signal supplying line is connected to the first gate line and the second initialization control line.

5. The display device of claim 1, further comprising:
a first bypass control line, a second bypass control line, and a third bypass control line respectively connected to the first pixel, the second pixel, and the third pixel and extending in the second direction on the display area.

6. The display device of claim 5,
wherein the light emission control signal supplying line is connected to the first light emission control line and the second light emission control line.

7. The display device of claim 5,
wherein the light emission control signal supplying line is connected to the first light emission control line, the second light emission control line, and the third light emission control line.

8. The display device of claim 5,
wherein the driving control signal supplying line is connected to the first gate line and the second initialization control line.

9. An organic light emitting display device, comprising:
a first pixel, a second pixel, and a third pixel arranged in a first direction on a display area of a display panel;
a data line connected to the first pixel, the second pixel, and the third pixel and extending in the first direction on the display area;
a first gate line, a second gate line, and a third gate line respectively connected to the first pixel, the second pixel, and the third pixel and extending in a second direction perpendicular to the first direction on the display area;
a first initialization control line, a second initialization control line, and a third initialization control line respectively connected to the first pixel, the second pixel, and the third pixel and extending in the second direction on the display area;
a first bypass control line, a second bypass control line, and a third bypass control line respectively connected to the first pixel, the second pixel, and the third pixel and extending in the second direction on the display area;
a first light emission control line, a second light emission control line, and a third light emission control line respectively connected to the first pixel, the second pixel, and the third pixel and extending in the second direction on the display area;
a driving control signal supplying line connected to at least one of the first gate line, the second gate line, and the third gate line and at least one of the first bypass control line, the second bypass control line, and the third bypass control line and extending in the first direction on the display area;
a light emission control signal supplying line connected to at least two of the first light emission control line, the second light emission control line, and the third light emission control line and extending in the first direction on the display area;
a data driver connected to the data line, configured to supply a data signal, and located at a drivers placement area, the drivers placement area being located outside the display area in the first direction and included in a non-display area;
a gate driver connected to the driving control signal supplying line, configured to supply a driving control signal, and located at the drivers placement area; and
a light emission control driver connected to the light emission control signal supplying line, configured to supply a light emission control signal, and located at the drivers placement area.

10. The display device of claim 9,
wherein the light emission control signal supplying line is connected to the first light emission control line and the second light emission control line.

11. The display device of claim 9,
wherein the light emission control signal supplying line is connected to the first light emission control line, the second light emission control line, and the third light emission control line.

12. The display device of claim 9,
wherein the driving control signal supplying line is connected tothe first gate line and the first bypass control line.

13. The display device of claim 9,
wherein the driving control signal supplying line is connected to at least one of the first initialization control line, the second initialization control line, and the third initialization control line.

14. The display device of claim 13,
wherein the driving control signal supplying line is connected to the first gate line, the second initialization control line, and the first bypass control line.

15. The display device of claim 13,
wherein the driving control signal supplying line is connected to the first gate line, the second initialization control line, and the second bypass control line.

16. An organic light emitting display device, comprising:
a first pixel, a second pixel, and a third pixel arranged in a first direction on a display area of a display panel;
a data line connected to the first pixel, the second pixel, and the third pixel and extending in the first direction on the display area;
a first gate line, a second gate line, and a third gate line respectively connected to the first pixel, the second pixel, and the third pixel and extending in a second direction perpendicular to the first direction on the display area;
a first initialization control line, a second initialization control line, and a third initialization control line respectively connected to the first pixel, the second pixel, and the third pixel and extending in the second direction on the display area;
a first bypass control line, a second bypass control line, and a third bypass control line respectively connected to the first pixel, the second pixel, and the third pixel and extending in the second direction on the display area;
a first light emission control line, a second light emission control line, and a third light emission control line respectively connected to the first pixel, the second pixel, and the third pixel and extending in the second direction on the display area;
a driving control signal supplying line connected to at least one of the first initialization control line, the second initialization control line, and the third initialization control line and at least one of the first bypass control line, the second bypass control line, and the third bypass control line and extending in the first direction on the display area;
a light emission control signal supplying line connected to at least two of the first light emission control line, the second light emission control line, and the third light emission control line and extending in the first direction on the display area;
a data driver connected to the data line, configured to supply a data signal, and located at a drivers placement area, the drivers placement area being located outside the display area in the first direction and included in a non-display area;
a gate driver connected to the driving control signal supplying line, configured to supply a driving control signal, and located at the drivers placement area; and
a light emission control driver connected to the light emission control signal supplying line, configured to supply a light emission control signal, and located at the drivers placement area.

17. The display device of claim 16,
wherein the light emission control signal supplying line is connected to the first light emission control line and the second light emission control line.

18. The display device of claim 16,
wherein the light emission control signal supplying line is connected to the first light emission control line, the second light emission control line, and the third light emission control line.

19. The display device of claim 16,
wherein the driving control signal supplying line is connected to the first initialization control line and the first bypass control line.
